(19) United States
(12) Patent Application Publication
(10) Pub. No.: US 2021/0387283 A1
(43) Pub. Date: Dec. 16, 2021

(54) LASER ANNEALING DEVICE AND LASER ANNEALING METHOD

(71) Applicant: V TECHNOLOGY CO., LTD., Yokohama-shi, Kanagawa (JP)

(72) Inventor: Michinobu MIZUMURA, Yokohama-shi, Kanagawa (JP)

(73) Assignee: V TECHNOLOGY CO., LTD., Yokohama-shi, Kanagawa (JP)

(21) Appl. No.: 17/284,880

(22) PCT Filed: Oct. 9, 2019
(86) PCT No.: PCT/JP2019/039860

§ 371 Date: Apr. 13, 2021

(30) Foreign Application Priority Data
Nov. 2, 2018 (JP) 2018-207240

(51) Int. Cl. B23K 26/073; B23K 26/08; H01L 27/12; H01L 21/268

(52) U.S. Cl. CPC B23K 26/0738; H01L 21/268; H01L 27/1285; B23K 26/0869

(57) ABSTRACT

To provide a laser annealing apparatus which is high efficiency of irradiation energy and capable of achieving uniformity in density of irradiation energy in a region irradiated with a laser beam.

SOLVING MEANS

Scheduled treatment regions of a treatment film are each defined in the form of a strip extending in a scanning direction. Irradiation surface areas of line beams are oriented to be inclined relative to the scanning direction within respective scheduled treatment regions.

### TECHNICAL FIELD

The present invention generally relates to a laser annealing apparatus and a laser annealing method.

### BACKGROUND ART

Thin film transistors (TFTs) are used as switching devices working to actively drive flat panel displays (FPDs), such as liquid crystal displays (LCDs), or organic electroluminescence displays (OLEDs). Amorphous silicon (a-Si) or polycrystalline silicon (P-Si) are used as material of semiconductor layers of the thin film transistors (which will be referred to below as TFTs).

Amorphous silicon is usually low in mobility that is a characteristic indicating the ease with which an electron moves therethrough. The amorphous silicon does not, thus satisfy requirements of high mobility needed by FPDs whose density and definition are being more enhanced. It is, therefore, advisable that channel layers of switching devices for FPDs be made from polycrystalline silicon that is much higher in mobility than amorphous silicon. A polycrystalline silicon film may be made by applying a laser beam to an amorphous silicon film to recrystallize amorphous silicon to form polycrystalline silicon. Patent literature 1 teaches a laser annealing method of reforming amorphous silicon, as created on an almost entire area of a surface of a glass substrate by emitting a laser beam in the shape of a line beam long enough to cover an entire width of the glass substrate, into polycrystalline silicon. Such a laser annealing method is capable of scanning the glass substrate one time with the laser beam to reform the whole of the amorphous silicon created on the surface of the glass substrate into polycrystalline silicon. Production of the above type of laser beam in the shape of a long line beam is usually achieved using a cylindrical lens having a length long enough to cover an entire width of a glass substrate.

### PRIOR ART DOCUMENT

### Patent Literature

### PATENT LITERATURE 1

### Japanese Patent First Publication No. 2013-191743

### SUMMARY OF THE INVENTION

### Problem to be Solved by the Invention

In recent years, the size of display substrates has exceeded 1 meter and become 2 or 3 meters long. It is difficult to produce such a long cylindrical lens, thus resulting in a difficulty in developing a line beam long enough to cover an entire width of the display substrate. In such a case, it is necessary to break down the surface of the substrate into a plurality of areas and anneal each of the areas using a line beam. This, however, leads to a risk that a laser-irradiated region may overlap each other over a boundary between the adjacent areas of the substrate or a non-laser irradiated region may occur. It is, therefore, impossible to ensure the uniformity of annealing of the whole surface of the substrate.

In the techniques disclosed in the above patent literature 1, a laser beam is emitted to the entire surface of the amorphous silicon film formed on the surface of the glass substrate. An area on which TFTs are fabricated is usually small. The amorphous silicon film on an area where no TFTs are formed is wastefully irradiated with a laser beam. The conventional laser annealing system is, therefore, low in energy efficiency. The conventional laser annealing system is required to slow down a relative scanning speed of the line beam or increase the number of pulses in order to emit a laser beam to a required area at a sufficient energy density. Such a conventional laser annealing system, therefore, faces problems that the energy efficiency is low, which leads to an increase in annealing cost, and a period of annealing time is undesirably long.

The present invention was made in view of the above problems. It is an object to provide a laser annealing apparatus and a laser annealing method which are high in efficiency of irradiation energy and capable of achieving uniformity in density of irradiation energy in a region irradiated with a laser beam without need for use of a long cylindrical lens.

### Means for Solving the Problem

In order to solve the above problems and achieve the object, there is provided an aspect of a laser annealing apparatus in which a treatment substrate and a laser emitter are movable relative to each other in a scanning direction, the treatment substrate having a surface on which a treatment film is formed, the laser emitter working to emit laser beams in shape of line beams along scheduled treatment regions defined on the treatment film to perform annealing treatment. The scheduled treatment regions are each defined to extend in the scanning direction in the form of a strip. The irradiation surface area is defined to have a length thereof inclined relative to the scanning direction within each of the scheduled treatment regions.

It is preferable in the above aspect that the plurality of scheduled treatment regions are arranged away from each other in a direction perpendicular to the scanning direction on the treatment film, and that the laser emitter is equipped with an optical system which irradiates each of the scheduled treatment regions with the line beam.

It is preferable in the above aspect that the laser emitter includes a set of a plurality of cylindrical lenses constituting the optical systems, the set of the cylindrical lenses are arranged integrally on a cylindrical array.

It is preferable in the above aspect that the line beams are pulse-oscillated, and that the relative movement is achieved in the scanning direction synchronously with each irradiation of pulses of the line beams by a fraction of a length of each of the line beams extending in the scanning direction.

It is preferable in the above aspect that the laser emitter performs continuous-wave oscillation of the line beams, and that a speed at which the laser emitter and treatment substrate are moved relative to each other is set to be constant.

It is preferable in the above aspect that the treatment film is an amorphous silicon film, and that each of the scheduled treatment region includes an array of areas where thin-film transistors are formed on the treatment substrate.

An aspect of a laser annealing method according to the invention is a laser annealing method which emits laser beams in shape of line beams along scheduled treatment regions defined on a treatment film disposed on a treatment substrate to perform annealing treatment and comprises: (a) defining each of the scheduled treatment regions to extend in a scanning direction in a form of a strip; (b) arranging the irradiation surface area to have a length thereof inclined relative to the scanning direction within each of the scheduled treatment regions; and (c) moving each of the line beams relative to one of the scheduled treatment regions in the scanning direction to anneal the treatment film.

It is preferable in the above aspect that the plurality of scheduled treatment regions are arranged away from each other in a direction perpendicular to the scanning direction on the treatment film, and that the line beams are emitted to the respective scheduled treatment regions using a set of optical systems one for covering each of the scheduled treatment regions.

It is preferable in the above aspect that the line beams are pulse-oscillated, and that the relative movement is achieved in the scanning direction synchronously with each irradiation of pulses of the line beams by a fraction of a length of each of the line beams extending in the scanning direction.

It is preferable in the above aspect that the line beams are continuous wave-oscillated, and that the line beams are moved at a constant speed relative to the respective scheduled treatment regions.

It is preferable in the above aspect that the treatment film is an amorphous silicon film, and that each of the scheduled treatment regions includes an array of areas where thin-film transistors are formed on the treatment substrate.

### Beneficial Advantage of the Invention

The laser annealing apparatus and the laser annealing method according to the present invention are capable of enhancing the efficiency in irradiation energy and also capable of achieving uniformity in density of irradiation energy in a region irradiated with a laser beam.

### BRIEF DESCRIPTION OF THE DRAWINGS

FIG. 1 is a schematic structural view which illustrates a laser annealing apparatus according to the first embodiment of the invention.

FIG. 2 is a perspective view which demonstrates emission of a line beam to a surface of an amorphous silicon film using a laser annealing apparatus according to the first embodiment of the invention.

FIG. 3 is a plan view which illustrates a cylindrical lens array in a laser annealing apparatus according to the first embodiment of the invention.

FIG. 4 is a plan view which illustrates annealing of a treatment substrate using a laser annealing apparatus according to the first embodiment of the invention.

FIGS. 5(A) to 5(D) are explanatory views which demonstrate time-sequential annealing operations performed on a scheduled treatment region on a treatment substrate using a laser annealing apparatus according to the first embodiment of the invention.

FIG. 6 is an explanatory view which represents an energy density in a widthwise direction of a scheduled treatment region annealed using a laser annealing apparatus according to the first embodiment of the invention.

FIG. 7 is an explanatory plan view which illustrates annealing of a treatment substrate performed using a laser annealing apparatus according to the second embodiment of the invention.

FIG. 8 is a perspective view which illustrates a reference example.

FIG. 9 is an explanatory view which represents an energy density in a widthwise direction of a scheduled treatment region annealed in a reference example.

### MODE FOR CARRYING OUT THE INVENTION

A laser annealing apparatus and a laser annealing method according to an embodiment of the invention will be described in detail below with reference to the drawings. The drawings are schematic diagrams. Dimensions of parts or a proportion in size between the parts in the drawings are, thus, different from actual ones. A dimensional relationship among the parts, a proportion in size of the parts, or shapes of the parts may also be different among the drawings.

### First Embodiment

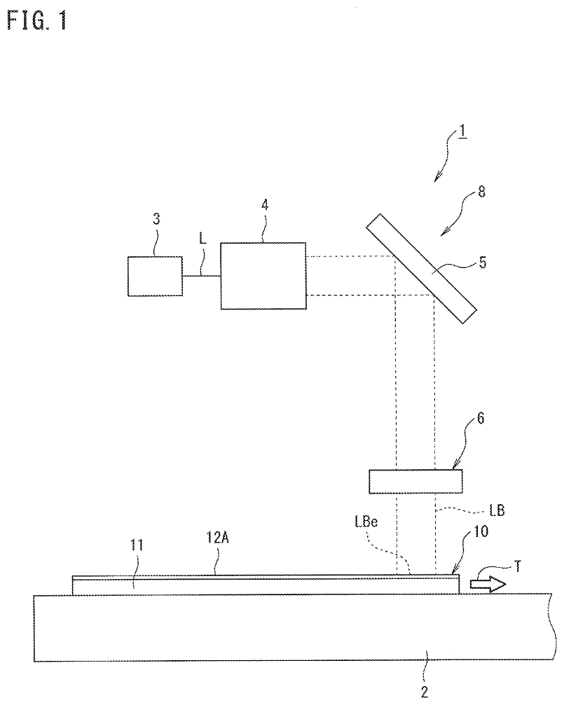

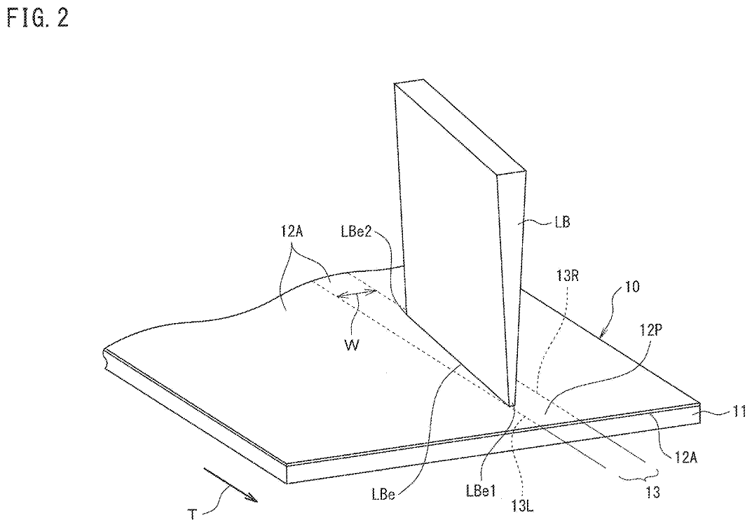

Prior to describing the structure of the laser annealing apparatus, a substrate to be annealed by the laser annealing apparatus will be discussed below. The treatment substrate 10 to be annealed, as illustrated in FIGS. 1 and 2, includes the glass substrate 11 and the amorphous silicon film 12A which is formed on an almost entire surface of the glass substrate 11 as treatment films. The treatment substrate 10 will eventually be a TFT substrate. Wiring patterns, such as gate lines, may be formed between the amorphous silicon film 12A and the glass substrate 11 depending on the structure of TFTs to be made.

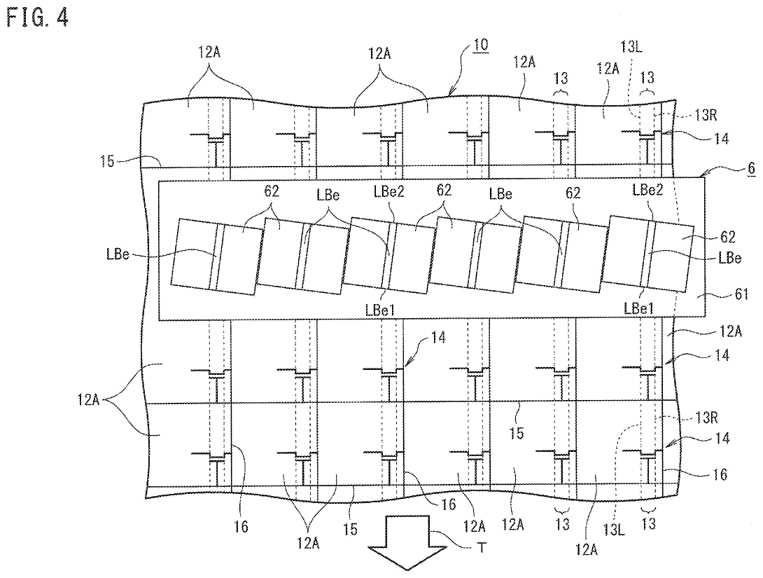

FIG. 4 illustrates TFTs which are not yet fabricated completely and shows planned TFT-fabrication regions 14 using TFT symbols. The treatment substrate 10, as clearly illustrated in FIG. 4, has a plurality of gate lines 15 and a plurality of data lines 16 formed thereon. The planned TFT-fabrication regions 14 are located near intersections between the gate lines 15 and the data lines 16.

The amorphous silicon film 12A, as illustrated in FIGS. 2 and 4, have defined thereon strip-shaped scheduled treatment regions 13 which extend in a scanning direction T. The scheduled treatment regions 13 are each formed to extend to include the planned TFT-fabrication regions 14 arranged in the scanning direction T. The scheduled treatment regions 13 are, as can be seen in FIG. 4, arranged at the same interval as the data lines 16 away from each other in a direction perpendicular to the scanning direction T. Each of the scheduled treatment regions 13 has a width W substantially identical with that of a TFT channel layer to be produced.

### Outline of Structure of Laser Annealing Apparatus

The structure of the laser annealing apparatus 1 according to this embodiment will be described below with reference to FIG. 1. The laser annealing apparatus 1 includes the base 2 and the laser emitter 8. The laser emitter 8 is equipped with the laser light source 3, the illumination optical system 4 including a beam homogenizer, the mirror 5, and the cylindrical lens array 6.

The treatment substrate 10 is, as illustrated in FIG. 1, disposed on the base 2. The treatment substrate 10 is movable relative to the laser emitter 8 in the scanning direction T. In this embodiment, the treatment substrate 10 is moved on the base 2 using a conveyer, not shown, in the scanning direction T.

The laser light source 3, as illustrated in FIG. 1, works to pulse-oscillate at a set frequency to produce the laser beams L. The illumination optical system 4 emits each of the laser beams L, as outputted from the laser light source 3, uniformly to a given spatial range. The laser beam L, as emitted from the illumination optical system 4 uniformly to the given spatial range to have an increased width, is reflected by the mirror 5 and then enters the cylindrical lens array 6. The cylindrical lens array 6 serves to create a plurality of line beams LB using the laser beams inputted thereto. Specifically, the laser emitter 8 is equipped with optical systems one for each of the scheduled treatment regions 13.

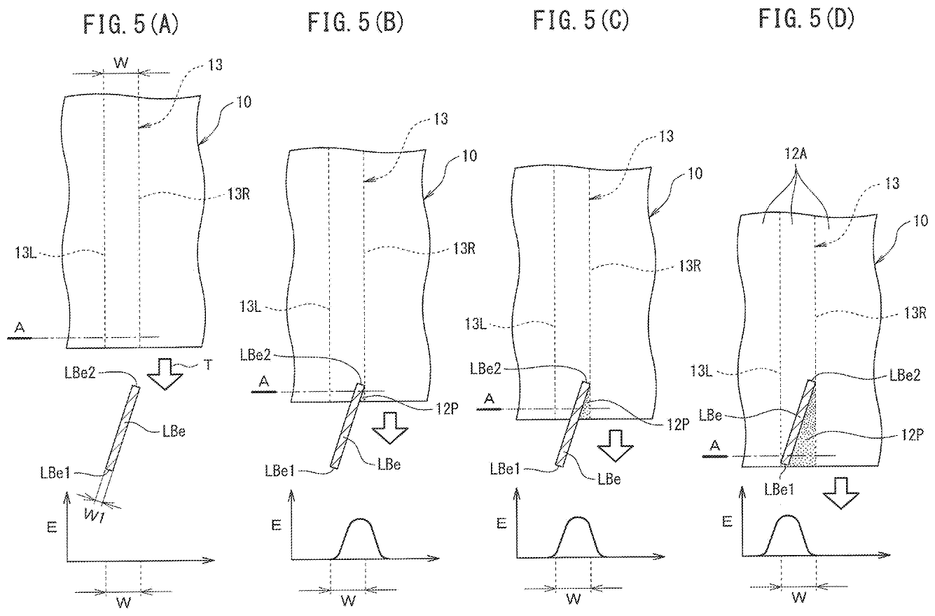

FIG. 2 illustrates one of the line beams LB produced by the cylindrical lens array 6. The line beam LB in FIG. 2 has an elongated irradiation surface area LBe illuminating the amorphous silicon film 12A disposed on the treatment substrate 10. The irradiation surface area LBe has a width W1 (see FIG. 5(A)) defined in a direction perpendicular to a lengthwise direction thereof. The width W1 is larger than a width W of each of the scheduled treatment regions 13 in a direction perpendicular to the scanning direction T. The width W1 extending perpendicular to the length of the irradiation surface area LBe may alternatively be selected to be smaller than the width W of the scheduled treatment regions 13 extending perpendicular to the scanning direction T.

The irradiation surface area LBe is provided to lie within each of the scheduled treatment regions 13 on the amorphous silicon film 12A. The irradiation surface area LBe is, as clearly illustrated in FIGS. 2 to 5(D), defined to have a length thereof inclined relative to the scanning direction T within the scheduled treatment region 13. Specifically, the length of the irradiation surface area LBe, as can be seen in FIG. 2, has the front end LBe1 disposed substantially in contact with the scheduled treatment region perimeter 13L that is one of perimeters of the scheduled treatment region 13 which are arranged away from each other in a widthwise direction of the scheduled treatment region 13. The length of the irradiation surface area LBe has the rear end LBe2 disposed substantially in contact with the scheduled treatment region perimeter 13R that is the other of the perimeters of the scheduled treatment region 13.

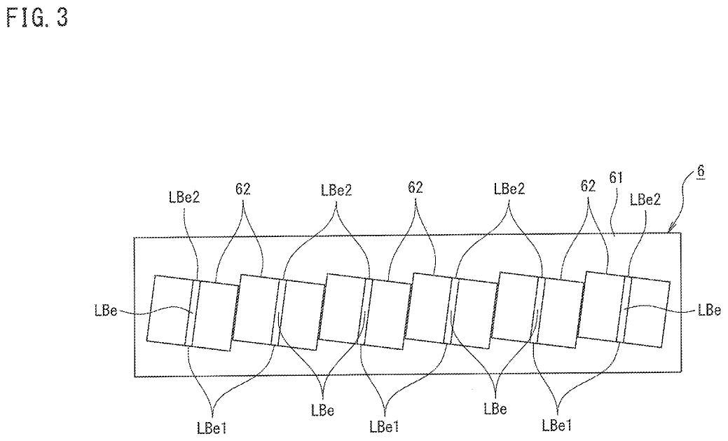

The cylindrical lens array 6, as illustrated in FIGS. 3 and 4, includes the array base plate 61 and a plurality of cylindrical lenses 62. The array base plate 61 extends perpendicular to the scanning direction T. the cylindrical lenses 62 are disposed integrally on the array base plate 61 in the form of an array extending perpendicular to the scanning direction T.

For the convenience of explanation, FIGS. 3 and 4 show each of the irradiation surface areas LBe of the line beams LB emitted from the cylindrical lenses 62 onto the treatment substrate 10, as schematically overlapping one of the cylindrical lenses 62. Each of the cylindrical lenses 62 is, as illustrated in FIGS. 3 and 4, is inclined relative to the scanning direction T to have a corresponding one of the irradiation surface areas LBe arranged in orientation, as shown in FIG. 2, relative to the amorphous silicon film 12A. Actually, the cylindrical lenses 62 are, as illustrated in FIG. 4, arranged to produce the line beams LB (i.e., the irradiation surface areas LBe), one for each of the scheduled treatment regions 13 defined on the amorphous silicon film 12A.

### Operation of Laser Annealing Apparatus

A leaser annealing method using the laser annealing apparatus 1 and operation will be described.

First, the treatment substrate 10 is, as illustrated in FIG. 1, disposed on the base 2 to orient the length of each of the scheduled treatment regions 13 extending parallel to the scanning direction T on the amorphous silicon film 12A.

Subsequently, the laser emitter 8 is activated to pulse-oscillate the line beams LB. The treatment substrate 10 is moved by a conveyer, not shown, in the scanning direction T along with the operation of the laser emitter 8. Each time the treatment substrate 10 is moved by a fraction (i.e., one of n equal parts) of the length of the irradiation surface area LBe along the scanning direction T, a laser is emitted.

When the treatment substrate 10 has passed by the laser emitter 8, the operations of the treatment substrate 10 and the laser emitter 8 are stopped to terminate the annealing process.

FIGS. 5(A) to 5(D) demonstrate time-sequential annealing operations executed by the laser annealing apparatus 1 on one of the scheduled treatment regions 13 and distributions of energy density on each of the scheduled treatment regions 13 upon every pulse oscillation.

The condition demonstrated in FIG. 5(A) is a condition where the treatment substrate 10 starts moving in the scanning direction T. The annealing is not yet executed.

The condition demonstrated in FIG. 5(B) is a condition where the treatment substrate 10 has arrived below the cylindrical lens array 6 to initiate the annealing. The irradiation surface area LBe of the line beam LB reaches a location A in the scheduled treatment region 13. A peak of the energy density, as represented in the distribution of energy density on a coordinate axis in the widthwise direction shown in a lower part of FIG. 5(B), lies near the scheduled treatment region perimeter 13R of the scheduled treatment region 13.

The condition demonstrated in FIG. 5(C) is a condition where the treatment substrate 10 has been moved in the scanning direction T from the location shown in FIG. 5(B) by a fraction (i.e., one of n equal parts) of the length of the irradiation surface area LBe extending in the scanning direction T. The peak of energy density at the location A is close to the center of the width of the scheduled treatment region 13. A portion of the scheduled treatment region 13 passed by the irradiation surface area LBe is annealed and recrystallized into the polycrystalline silicon film 12P.

The condition demonstrated in FIG. 5(D) is a condition where the treatment substrate 10 is further moved to have a peak of energy density which is close to the scheduled treatment region perimeter 13L. A portion of the scheduled treatment region 13 occupying almost the width thereof at the location A is reformed into the polycrystalline silicon film 12P.

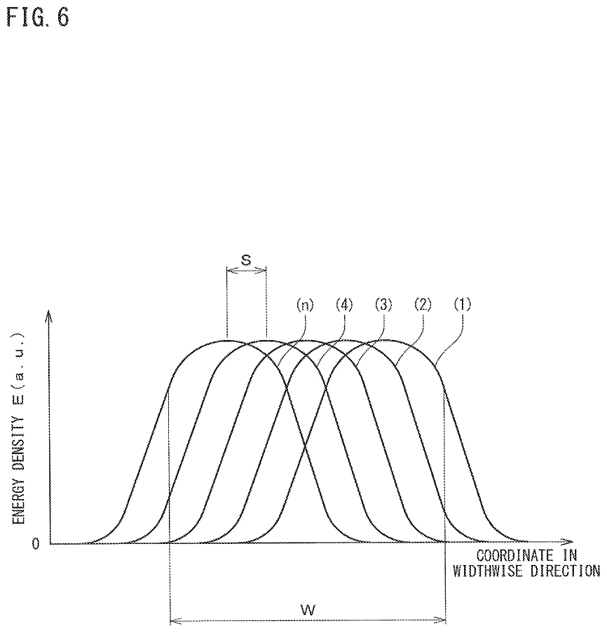

FIG. 6 represents a transition of the energy density when the elongated irradiation surface area LBe has passed the location A on the scheduled treatment region 13 in an inclined orientation relative to the scheduled treatment region 13. The graph in FIG. 6 shows that densities of energy of laser irradiation indicated by (1) to (n) are arranged close to each other in the widthwise direction of the scheduled treatment region 13, so that the peaks of the energy densities (1) to (n) are substantially aligned with each other. This causes the densities of energy to be uniformly distributed anywhere on the scheduled treatment region 13 passed by the irradiation surface area LBe both in the scanning direction T and in the widthwise direction. The laser annealing apparatus 1 is, therefore, capable of forming the polycrystalline silicon film 12P that is uniform in quality in each of the scheduled treatment regions 13. A shift S from one to the other of the respective adjacent peaks of the energy densities demonstrated in FIG. 6 is decreased with an increase in number of pulse oscillations of the laser beam L to homogenize the energy densities (1) to (n).

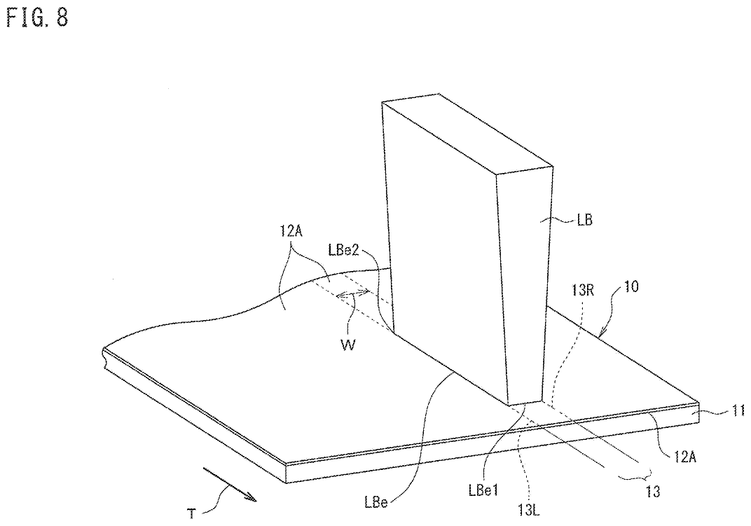

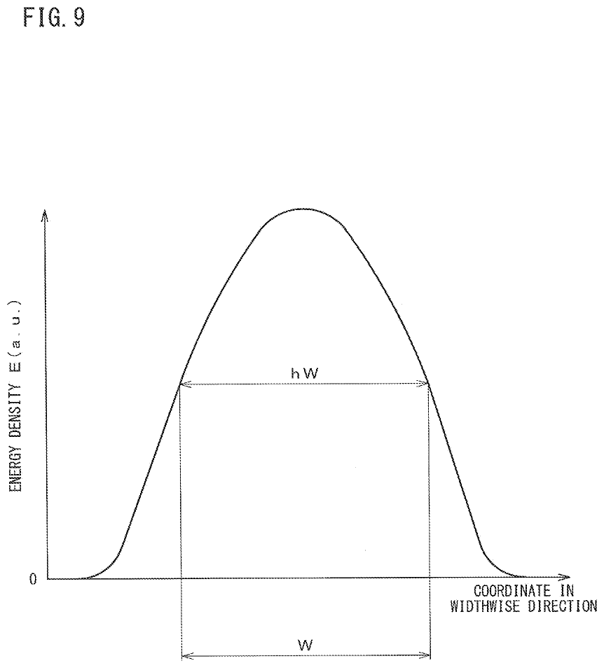

FIG. 8 is an explanatory view illustrating a reference example. FIG. 9 demonstrates a density of energy a portion of the film 12A has been subjected so that it is annealed in a manner, as illustrated in FIG. 9, on a coordinate axis in the widthwise direction. In the reference example in FIG. 8, the irradiation surface area LBe is defined to have a width identical with the width W of the scheduled treatment region 13. The irradiation surface area LBe is oriented not to be inclined in the scanning direction T and irradiated with a laser beam. In the reference example, there is no transition of a peak of the energy density in the widthwise direction of the scheduled treatment region 13, so that a profile of energy density of the line beam LB reflects directly on the scheduled treatment region 13.

### Beneficial Advantages Offered by Laser Annealing Apparatus and Laser Annealing Method

The laser annealing apparatus 1 and the laser annealing method in this embodiment are capable of homogenizing the density of energy of laser irradiation in the scheduled treatment regions 13. This improves the quality of the polycrystalline silicon film 12P into which the amorphous silicon film 12A is reformed and achieves the production of the polycrystalline silicon film 12P which is high in mobility, thereby enhancing the performance of a display device.

The laser annealing apparatus 1 and the laser annealing method in this embodiment are designed to use the cylindrical lens array 6, thereby enabling each of the cylindrical lenses 62 to be reduced in size thereof and also enabling production cost of the laser annealing apparatus 1 to be decreased.

The laser annealing apparatus 1 in this embodiment is designed to emit a laser beam only to each of the strip-shaped scheduled treatment regions 13 which occupies the planned TFT-fabrication regions 14, thereby enhancing the efficiency of irradiation energy.

### Second Embodiment

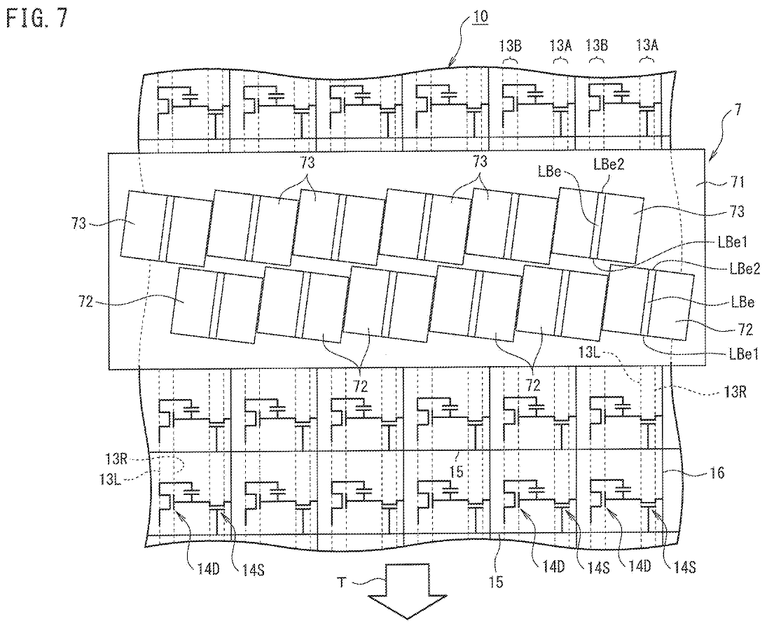

FIG. 7 illustrates the cylindrical lens array 7 of a laser annealing apparatus according to the second embodiment of the invention. The cylindrical lens array 7 includes an array of cylindrical lenses 72 which are arranged adjacent each other in a direction perpendicular to the scanning direction T on the array substrate 71. The cylindrical lens array 7 also includes an array of cylindrical lenses 73 which extends parallel to the array of the cylindrical lenses 72.

The treatment substrate 10 used in this embodiment has the planned selection TFT-fabrication region 14S and the planned driving TFT-fabrication region 14D within each region of one pixel. The cylindrical lenses 72 are located one for covering each set of the planned selection TFT-fabrication region 14S and the planned driving TFT-fabrication region 14D. Other arrangements of the laser annealing apparatus in this embodiment are identical with those in the laser annealing apparatus 1 in the first embodiment.

This embodiment is equipped with the array of the cylindrical lenses 72 and the array of the cylindrical lenses 73, thereby ensuring the stability in achieving the annealing even when an interval between the scheduled treatment regions 13A and 13B which are arranged adjacent each other in a direction perpendicular to the scanning direction T is small. This embodiment offers substantially same beneficial advantages as those in the first embodiment.

### Other Embodiments

While the embodiments have been described, it should be appreciated that the statements and the drawings constituting part of this disclosure limit the invention. Various alternative embodiments or operability technologies will be apparent to those skilled in the art from this disclosure.

For instance, the laser annealing apparatus in each of the above embodiments uses the amorphous silicon film 12A use in reforming the polycrystalline silicon film 12P, but however, it may also be employed in annealing another type of material film.

The laser annealing apparatus in each of the above embodiments is designed to anneal the amorphous silicon film 12A to produce TFT channel layers, but however, it may alternatively be annealed to produce polycrystalline silicon electrodes.

The laser annealing apparatus in each of the above embodiments works to pulse-oscillate the laser beam, but however, may alternatively be designed to have the laser emitter 8 to continuous wave-oscillate the line beam LB and set the speed at which the laser emitter 8 and the base 2 are moved relative to each other to be constant.

The laser annealing apparatus in each of the above embodiments uses the cylindrical lenses 62 or the cylindrical lenses 72 and 73 as optical systems for producing the line beams LB, but however, may alternatively be designed to use another type of optical systems capable of generating the line beams LB.

### EXPLANATION OF REFERENCE SYMBOLS

1 laser annealing apparatus
2 base
3 laser light source
4 illumination optical system
5 mirror
6, 7 cylindrical lens array
61 array substrate
62 cylindrical lens
71 array substrate
8 laser emitter
10 treatment substrate
11 glass substrate
12A amorphous silicon film
12P polycrystalline silicon film
13, 13A, 13B scheduled treatment region
13R, 13L scheduled treatment region perimeter
14 planned TFT-fabrication region
14S planned selection TFT-fabrication region
14D planned driving TFT-fabrication region
15 gate line
16 data line
LB line beam
LBe irradiation surface area
LBe1 front end
LBe2 rear end

1. A laser annealing apparatus in which a treatment substrate and a laser emitter are movable relative to each other in a scanning direction, the treatment substrate having a surface on which a treatment film is formed, the laser emitter working to emit laser beams in shape of line beams along scheduled treatment regions defined on the treatment film to perform annealing treatment, wherein
the scheduled treatment regions are each defined to extend in the scanning direction in a form of a strip, and
an irradiation surface area is defined to have a length thereof inclined relative to the scanning direction within each of the scheduled treatment regions.

2. The laser annealing apparatus as set forth in claim 1, wherein the plurality of scheduled treatment regions are arranged away from each other in a direction perpendicular to the scanning direction on the treatment film, and
the laser emitter is equipped with an optical system which irradiates each of the scheduled treatment regions with the line beam.

3. The laser annealing apparatus as set forth in claim 2, wherein the laser emitter includes a set of plurality of cylindrical lenses constituting the optical system, the set of the cylindrical lenses being arranged integrally on an array substrate.

4. The laser annealing apparatus as set forth in claim 1, wherein the line beams are pulse-oscillated, and
the relative movement is achieved in the scanning direction synchronously with each irradiation of pulses of the line beams by a fraction of a length of each of the line beams extending in the scanning direction.

5. The laser annealing apparatus as set forth in claim 1, wherein the laser emitter performs continuous-wave oscillation of the line beams, and
a speed at which the laser emitter and treatment substrate are moved relative to each other is set to be constant.

6. The laser annealing apparatus as set forth in claim 1, wherein the treatment film is an amorphous silicon film, and
each of the scheduled treatment region includes an array of areas where thin-film transistors are formed on the treatment substrate.

7. A laser annealing method which emits laser beams in shape of line beams along scheduled treatment regions defined on a treatment film disposed on a treatment substrate to perform annealing treatment, comprising:
defining each of the scheduled treatment regions to extend in a scanning direction in a form of a strip;
arranging an irradiation surface area to have a length thereof inclined relative to the scanning direction within each of the scheduled treatment regions; and
moving each of the line beams relative to one of the scheduled treatment regions in the scanning direction to anneal the treatment film.

8. The laser annealing method as set forth in claim 7, wherein the plurality of scheduled treatment regions are arranged away from each other in a direction perpendicular to the scanning direction on the treatment film, and
the line beams are emitted to the respective scheduled treatment regions using a set of optical systems one for covering each of the scheduled treatment regions.

9. The laser annealing method as set forth in claim 7, wherein the line beams are pulse-oscillated, and
the relative movement is achieved in the scanning direction synchronously with each irradiation of pulses of the line beams by a fraction of a length of each of the line beams extending in the scanning direction.

10. The laser annealing method as set forth in claim 7, wherein the line beams are continuous wave-oscillated, and
the line beams are moved at a constant speed relative to the respective scheduled treatment regions.

11. The laser annealing method as set forth in claim 7, wherein the treatment film is an amorphous silicon film, and
each of the scheduled treatment regions includes an array of areas where thin-film transistors are formed on the treatment substrate.
